(19) United States
(12) Patent Application Publication
(10) Pub. No.: US 2026/0231517 A1
(43) Pub. Date: Aug. 6, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Hsin WANG, New Taipei City (TW); Olivia Pei-Hua LEE, Hsinchu County (TW); Sung-Li WANG, Hsinchu County (TW); Jhih-Rong HUANG, Hsinchu County (TW); Tzer-Min SHEN, Hsinchu City (TW)

(73) Assignee: TAIWAN SEMICONDUCTOR MANUFACTURING COMPANY, LTD., Hsinchu (TW)

(21) Appl. No.: 19/046,741

(22) Filed: Feb. 6, 2025

(51) Int. Cl. H10D 84/85; H10D 30/00; H10D 30/01; H10D 62/10; H10D 62/13; H10D 64/23; H10D 64/62; H10D 84/01

(52) U.S. Cl. CPC H10D 84/851; H10D 30/0191; H10D 30/502; H10D 62/121; H10D 62/151; H10D 64/254; H10D 64/256; H10D 64/62; H10D 84/0186; H10D 84/0188

(57) ABSTRACT

A semiconductor device includes a first device, comprising a first semiconductor channel layer, a first source/drain structure electrically connected to the first semiconductor channel layer, and a first gate structure over the first semiconductor channel layer. A contact etch stop layer (CESL) is over the first source/drain structure. An interlayer dielectric (ILD) layer is over the CESL, wherein a dielectric constant of the CESL is greater than a dielectric constant of the ILD layer. A source/drain contact extends through the ILD layer to electrically couple to the first source/drain structure, wherein an electrical conductivity of the source/drain contact is greater than an electrical conductivity of the first source/drain structure, and wherein the source/drain contact comprises a dipole layer, a metal oxide layer over the dipole layer, and a metal layer over the metal oxide layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 10B illustrate a method in various stages of forming a semiconductor device in accordance with some embodiments of the present disclosure.

FIGS. 11A and 11B are schematic views of band structures of semiconductor devices in accordance with some embodiments of the present disclosure.

FIG. 12 is a schematic view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

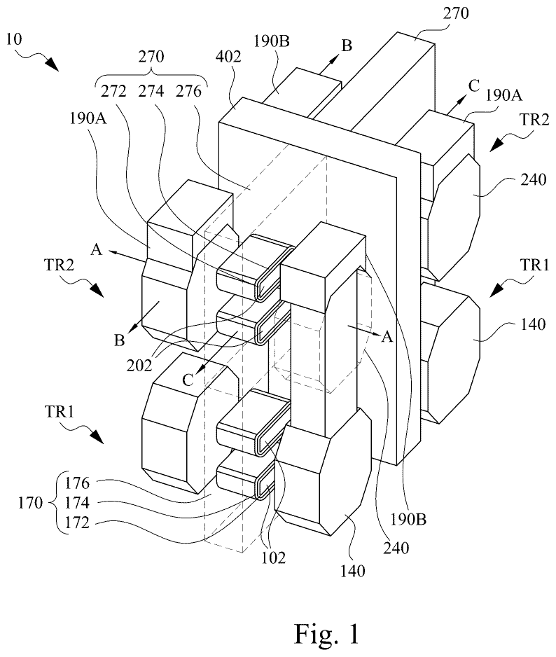

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, first transistors TR1 are disposed over a substrate (not shown), and second transistors TR2 are disposed vertically above the respective first transistors TR1. In some embodiments, the first transistors TR1 and the second transistors TR2 each may be field effect transistor (FET) and may both include gate-all-around (GAA) configuration, and thus the first transistors TR1 and the second transistors TR2 can also be referred to as GAA FETs. Each of the first transistors TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, each of the second transistors TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, each of the first transistors TR1 has a05 first conductivity type (e.g., p-type) and each of the second transistors TR2 has a second conductivity type (e.g., n-type) different from the first conductivity type. In some embodiments, the first transistors TR1 can be referred to as P-FETs, and the second transistors TR2 can be referred to as N-FETs.

A dielectric structure 402 is disposed between two adjacent first transistors TR1, so as to electrically isolate the two adjacent first transistors TR1. Similarly, the dielectric structure 402 is disposed between two adjacent second transistors TR2, so as to electrically isolate the two adjacent second transistors TR2.

The CFET 10 further includes source/drain contacts 190A and 190B. The source/drain contacts 190A and 190B are disposed over the respective second source/drain epitaxy structures 240. In some embodiments, the source/drain contact 190A is in contact with top surface of the corresponding second source/drain epitaxy structure 240. On the other hand, the source/drain contact 190B may penetrate through the second source/drain epitaxy structure 240, and extends downwardly to top surface of the corresponding first source/drain epitaxy structure 140. As a result, the source/drain contact 190B electrically connects the second source/drain epitaxy structure 240 and the underlying first source/drain epitaxy structure 140.

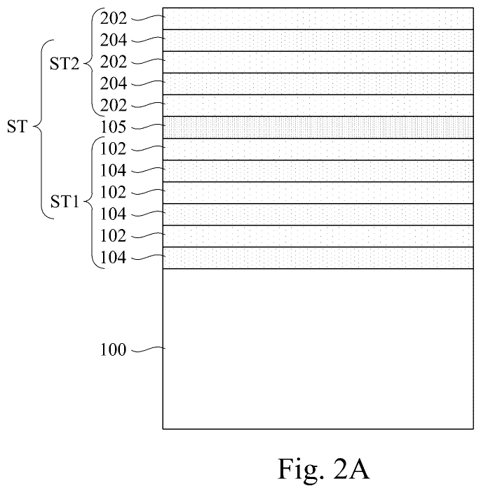

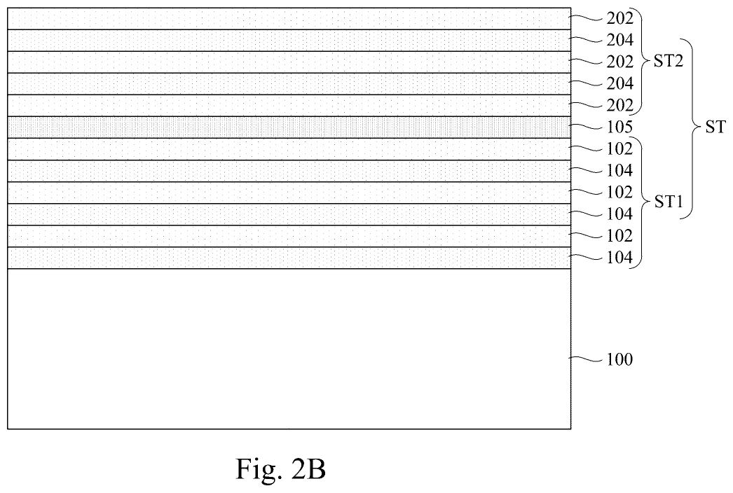

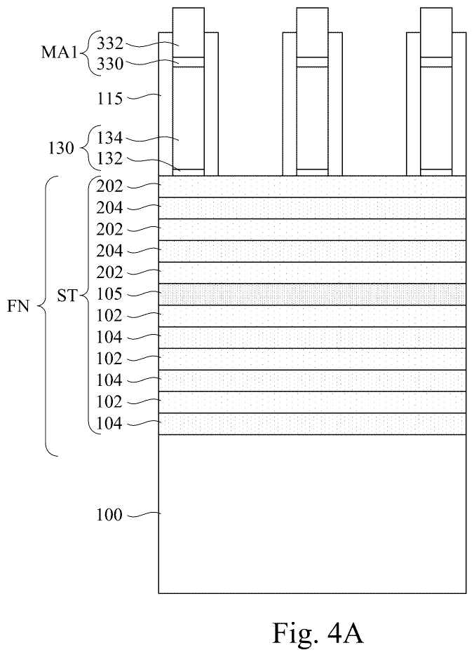

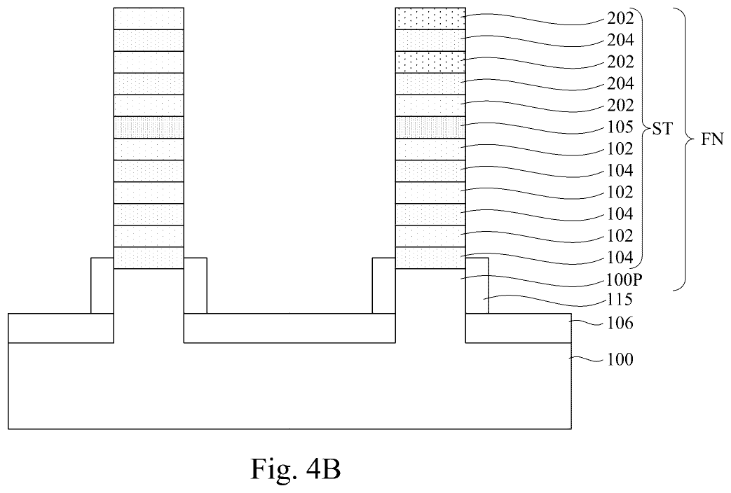

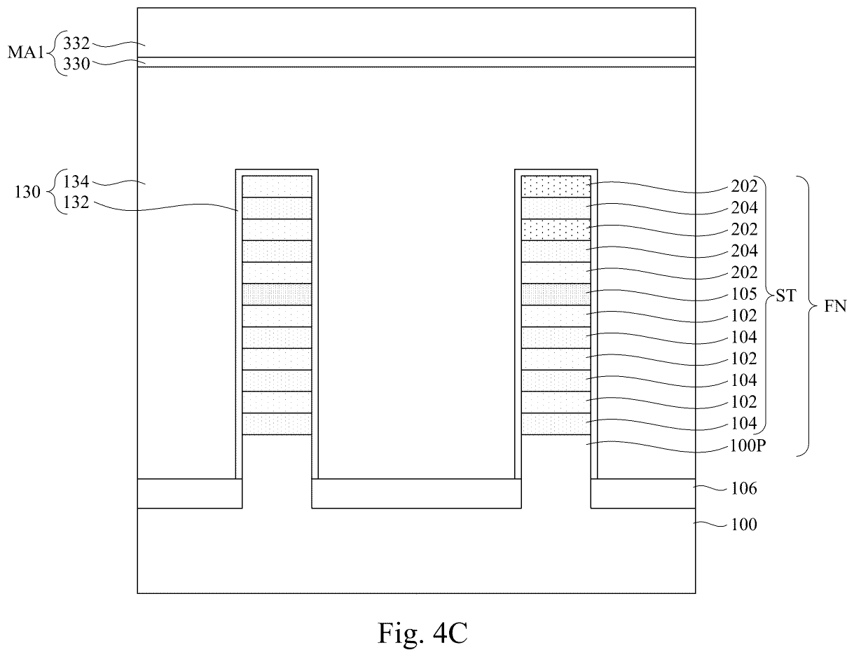

FIGS. 2A to 10B illustrate a method in various stages of forming a semiconductor device in accordance with some embodiments of the present disclosure. It is noted that FIGS. 2A, 3A, 4A, 5A, 6A, 7A, 8A, 9A, and 10A include cross-sectional views the same as the cross-sectional view along line A-A of FIG. 1. FIGS. 2B, 3B, 4B, 5B, 6B, 7B, 8B, 9B, and 10B include cross-sectional views the same as the cross-sectional view along line B-B of FIG. 1. FIGS. 4C, 7C, and 8C, include cross-sectional views the same as the cross-sectional view along line C-C of FIG. 1. Although FIGS. 2A to 10B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 10B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 60 percent and about 80 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

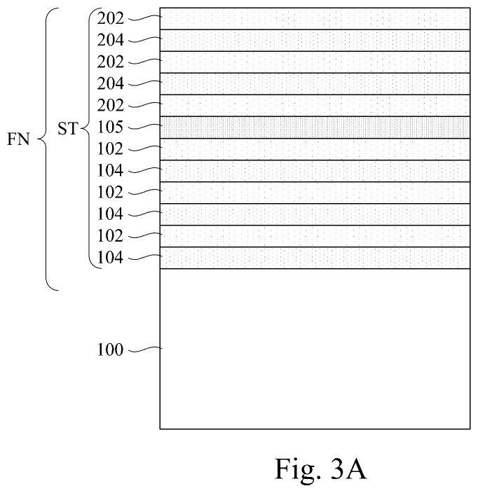

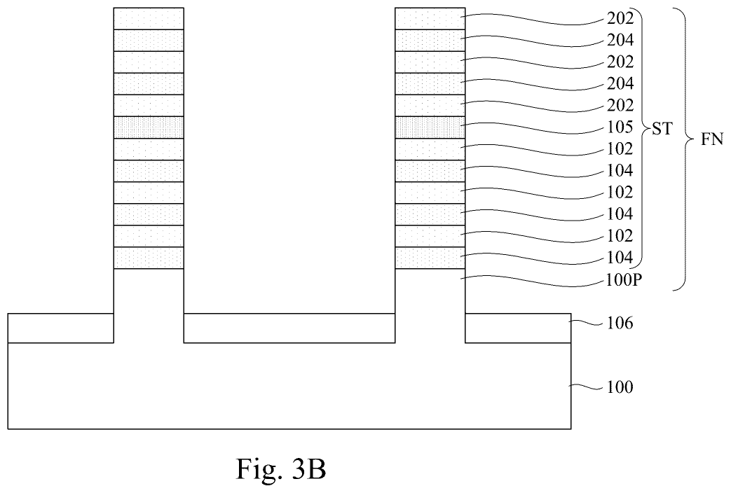

Reference is made to FIGS. 3A and 3B. A patterning process is performed to the semiconductor stack ST and the substrate 100 to form fin structures FN. In some embodiments, the patterning process may include forming a patterned photoresist layer over the stack ST, and then performing an etching process to remove unwanted portions of the semiconductor stack ST and the substrate 100 exposed by the patterned photoresist layer. Each of the fin structures FN may include a remaining portion of the semiconductor stack ST and a semiconductor strip 100P protruding over the substrate 100. In some embodiments, the etching process may include wet etch, dry etch, or the like.

After the fin structures FN are formed, isolation structures 106 are formed over the substrate 100 and laterally surrounding the fin structures FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

Reference is made to FIGS. 4A, 4B, and 4C. Dummy gate structures 130 are formed over the substrate 100 and crossing the fin structures FN (see FIG. 4C). In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of each of the dummy gate structures 130 (see FIG. 4A), and on opposite sidewalls of the fin structures FN (see FIG. 4B). In some embodiments, portions of the spacers 115 on opposite sidewalls of each of the dummy gate structures 130 can be referred to as gate spacers, and portions of the spacers 115 on opposite sidewalls of the fin structures FN can be referred to as fin spacers. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structures FN. In some embodiments, the remaining vertical portions of the spacer layer can be referred to as the spacers 115. The spacer layer may be deposited using techniques such CVD, ALD, or the like.

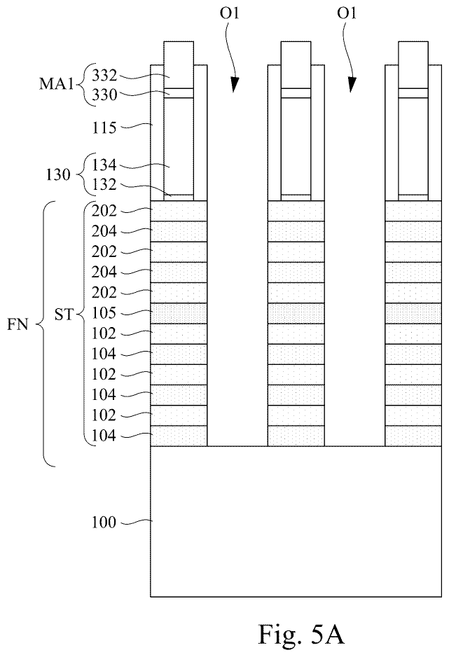

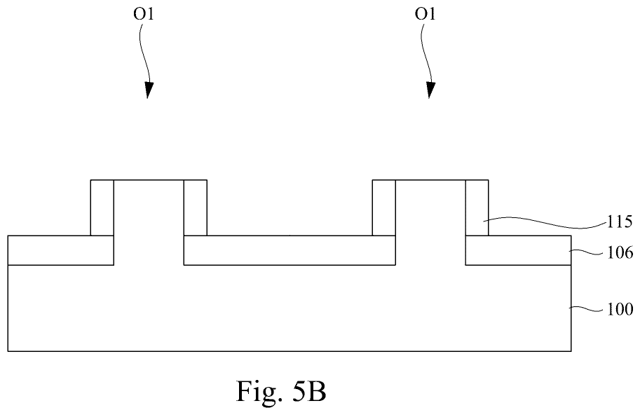

Reference is made to FIGS. 5A and 5B. An etching process is performed to remove portions of the fin structures FN (or the stacks ST) by using the dummy gate structures 130 and the spacers 115 as etch mask, so as to form source/drain openings O1 in the fin structures FN (or in the stacks ST). In some embodiments, the etching process may be wet etch, dry etch, or combinations thereof. In some embodiments, the bottommost ends of the source/drain openings O1 may be lower than the bottommost semiconductor layer 104.

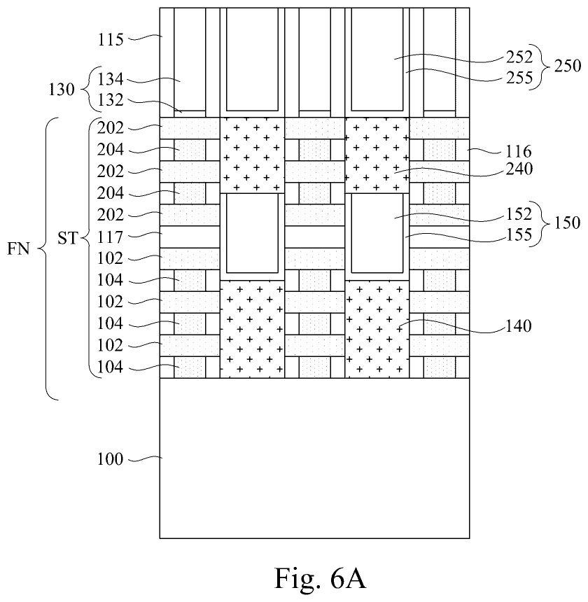

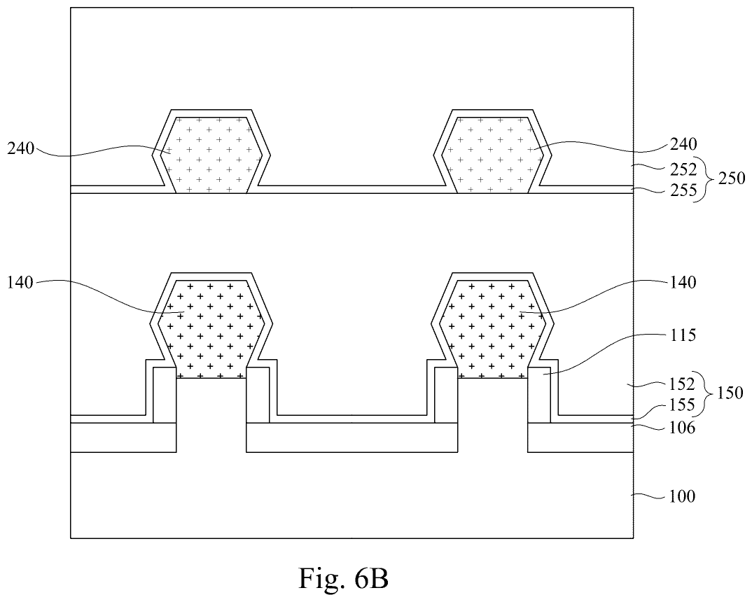

Reference is made to FIGS. 6A and 6B. Inner spacers 116 and dielectric isolation layers 117 are formed. Forming inner spacers 116 and dielectric isolation layers 117 may include an etching process that laterally etches the semiconductor layers 104 and 204 and removes the semiconductor layers 105. The etching process may be isotropic and may be selective to the material of the semiconductor layers 104, 105, and 204, so that the semiconductor layers 104, 105, and 204 are etched at a faster rate than the semiconductor layers 102 and 202. The etching process may also be selective to the material of the semiconductor layers 105, so that the semiconductor layers 105 are etched at a faster rate than the semiconductor layers 104 and 204. In this manner, the semiconductor layers 105 may be completely removed, while the semiconductor layers 104 and 204 are laterally shortened. In some embodiments where the semiconductor layers 105 are formed of germanium or silicon germanium with a higher germanium atomic percentage than the semiconductor layers 104 and 204, the semiconductor layers 104 and 204 are formed of silicon germanium with a lower germanium atomic percentage than the semiconductor layers 105, and the semiconductor layers 102 and 104 are formed of silicon free from germanium, the etch process may comprise a dry etch process using chlorine-containing gas, with or without a plasma.

Inner spacers 116 are formed on sidewalls of the recessed semiconductor layers 104 and 204, and dielectric isolation layers 117 are formed between the topmost semiconductor layer 102 and the bottommost semiconductor layer 104. As subsequently described in greater detail, source/drain structures will be subsequently formed in the source/drain openings O1, and the semiconductor layers 104 and 204 will be replaced with corresponding gate structures. The inner spacers 116 act as isolation features between the subsequently formed source/drain structures and the subsequently formed gate structures. Further, the inner spacers 116 may be used to prevent damage to the subsequently formed source/drain structures by subsequent etch processes, such as the etch processes used to form gate structures. Dielectric isolation layers 117, on the other hand, are used to isolate the upper semiconductor layers 104 from the lower semiconductor layers 102.

The inner spacers 116 and the dielectric isolation layers 117 may be formed by conformally depositing an insulating material in the source/drain openings O1, on sidewalls of the semiconductor layers 104 and 204, and in the gap between the topmost semiconductor layer 102 and the bottommost semiconductor layer 104, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the semiconductor layers 104 and 204 (thus forming the inner spacers 116) and has portions remaining in the gap between the topmost semiconductor layer 102 and the bottommost semiconductor layer 104 (thus forming the dielectric isolation layers 117). As a result, the inner spacers 116 and the dielectric isolation layers 117 may be made of the same dielectric material.

First source/drain epitaxy structures 140 are formed in the openings O1, respectively. The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the substrate 100 and the exposed surfaces of the semiconductor layers 102. In some embodiments, an implantation process may be performed to the first source/drain epitaxy structures 140. For example, the implantation process may include p-type dopants, such as boron (B), gallium (Ga), indium (In), aluminium (Al), or the like, such that the first source/drain epitaxy structures 140 are p-type epitaxy structures. In some embodiments where the first source/drain epitaxy structures 140 are p-type epitaxy structures, the first source/drain epitaxy structures 140 may be made of silicon germanium (SiGe) or silicon (Si).

A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152, such that sidewalls of the semiconductor layers 202 are exposed through the source/drain openings O1. In some embodiments, the CESL 155 and the ILD layer 152 can be collectively referred to as an isolation structure 150. In some embodiments, the topmost semiconductor layer 102 and the bottommost semiconductor layer 202 are in contact with the CESL 155 of the isolation structure 150.

In some embodiments, the CESL 155 may be nitride (such as silicon nitride), and the ILD layer 152 may be oxide (such as silicon oxide). In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques. In some embodiments, a dielectric constant of the CESL 155 is greater than a dielectric constant of the ILD layer 152.

Second source/drain epitaxy structures 240 are formed on opposite ends of each of the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 240. For example, the implantation process may include n-type dopants, such as phosphorus (P), arsenic (As), or antimony (Sb), or the like, such that the second source/drain epitaxy structures 240 are n-type epitaxy structures. In some embodiments where the second source/drain epitaxy structures 240 are n-type epitaxy structures, the second source/drain epitaxy structures 240 may be made of silicon (Si).

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively. For example, the CESL 255 may be nitride (such as silicon nitride), and the ILD layer 252 may be oxide (such as silicon oxide). In some embodiments, a dielectric constant of the CESL 255 is greater than a dielectric constant of the ILD layer 252.

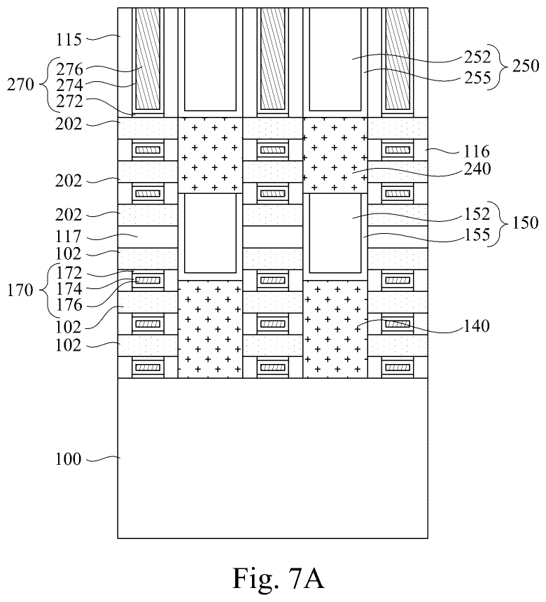

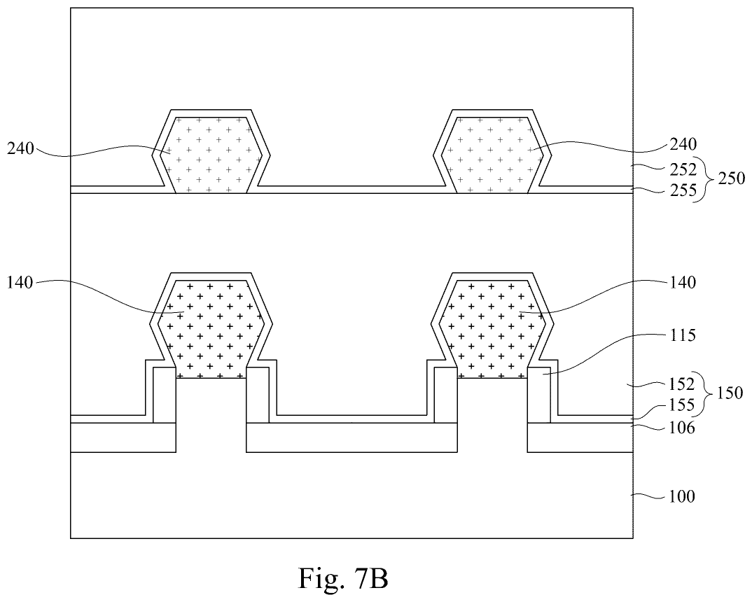

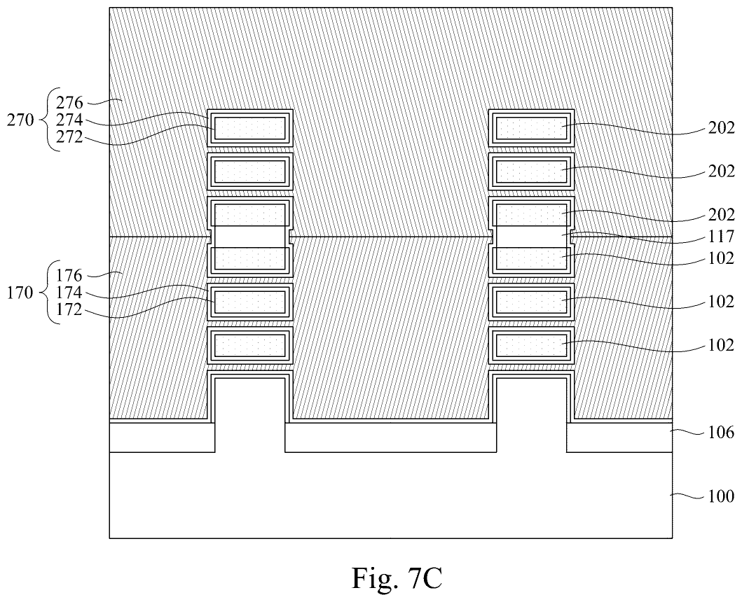

Reference is made to FIGS. 7A, 7B, and 7C. The dummy gate structures 130 are removed to form gate trenches between each pair of the gate spacers 115.

Then, an etching process is performed to remove the semiconductor layers 104 and 204 through the gate trenches, such that the semiconductor layers 102 and 202 are suspended over the substrate 100 (see FIG. 7C).

Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 are formed in the gate trenches and over the gate dielectric layers 174. The gate electrodes 176 are then etched back, such that the remaining gate electrodes 176 are at the lower portion of the gate trenches. Accordingly, first metal gate structures 170 are formed. In greater detail, the first metal gate structures 170 are formed in bottom portions of the gate trenches, such that the first metal gate structures 170 may wrap around the respective semiconductor layers 102. In some embodiments, each of the first metal gate structures 170 may include the interfacial layer 172, the gate dielectric layer 174 over the interfacial layer 172, and the gate electrode 176 over the gate dielectric layer 174.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the dielectric constants of the gate dielectric layers 174 and 274 may be greater than the dielectric constants of the spacers 115 and the dielectric constants of the CESLs 155 and 255.

The gate electrodes 176 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TR1 asi₂, NiSi₂, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal may include tungsten (W), aluminum (Al), copper (Cu), or another suitable conductive material(s).

Gate electrodes 276 are formed in the gate trenches and over the first metal gate structures 170. Accordingly, second metal gate structures 270 are formed. In greater detail, the second metal gate structures 270 are formed in upper portions of the gate trenches and above the first metal gate structures 170, such that the second metal gate structures 270 may wrap around the respective semiconductor layers 202. In some embodiments, each of the second metal gate structures 270 may include the interfacial layer 272, the gate dielectric layer 274 over the interfacial layer 272, and the gate electrode 276 over the gate dielectric layer 274. The materials of the gate electrode 276 may be similar to those described with respect to the gate electrode 176, and thus relevant details will not be repeated for brevity.

The first metal gate structure 170, the first source/drain epitaxy structures 140 on opposite sides of the first metal gate structure 170, and the semiconductor layers 102 that are in contact with the first source/drain epitaxy structures 140 may collectively serve as the first transistor TR1 as described in FIG. 1. In such condition, the semiconductor layers 102 that are in contact with the first source/drain epitaxy structures 140 may also be referred to as channel layers of the first transistor TR1. Similarly, the second metal gate structure 270, the second source/drain epitaxy structures 240 on opposite sides of the second metal gate structure 270, and the semiconductor layers 202 that are in contact with the second source/drain epitaxy structures 240 may collectively serve as the second transistor TR2 as described in FIG. 1. In such condition, the semiconductor layers 202 that are in contact with the second source/drain epitaxy structures 240 may also be referred to as channel layers of the second transistor TR2. In FIG. 7A, opposite ends of the topmost semiconductor layer 102 are in contact with the isolation structures 150, and are not in contact with the first source/drain epitaxy structures 140. Thus, the topmost semiconductor layer 102 may not function as a channel layer of the first transistor TR1. Similarly, opposite ends of the bottommost semiconductor layer 202 are in contact with the isolation structure 150, and are not in contact with the second source/drain epitaxy structures 240. Thus, the topmost bottommost semiconductor layer 202 may not function as a channel layer of the second transistor TR2.

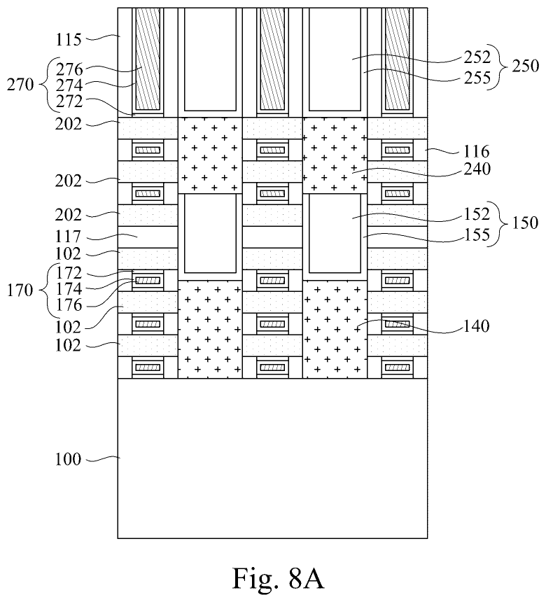

Reference is made to FIGS. 8A and 8B, and 8C. A dielectric structure 402 is formed. As shown in FIG. 8C, the dielectric structure 402 may cut through the first metal gate structure 170 and the second metal gate structure 270, so as to divide the first metal gate structure 170 and the second metal gate structure 270 into separated first metal gate structures 170 and separated second metal gate structures 270. As shown in FIG. 8B, the dielectric structure 402 may also cut through the isolation structures 150 and 250. In some embodiments, the dielectric structure 402 may extend through the isolation structures 106 and in contact with the substrate 100. In some embodiments, the dielectric structure 402 may also be referred to as a cut-metal-gate (CMG) isolation structure.

The dielectric structure 402 may be made of nitride (e.g., silicon nitride), oxide (e.g., silicon oxide), combinations thereof, or suitable dielectric material. The dielectric structure 402 may be formed by, for example, etching the first metal gate structure 170, the second metal gate structure 270, and the isolation structures 150 and 250 to form an opening, depositing a dielectric material in the opening, and then performing a planarization process (such as CMP) to remove excess materials of the dielectric material.

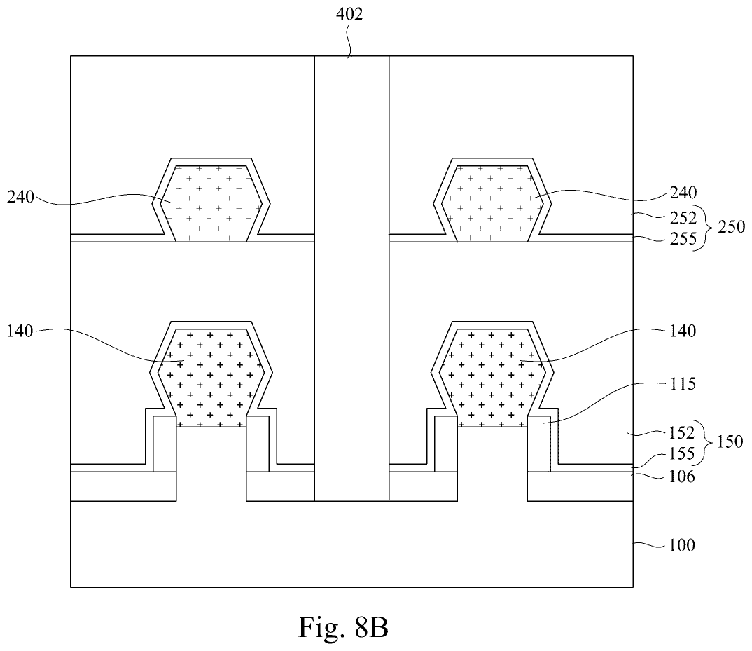

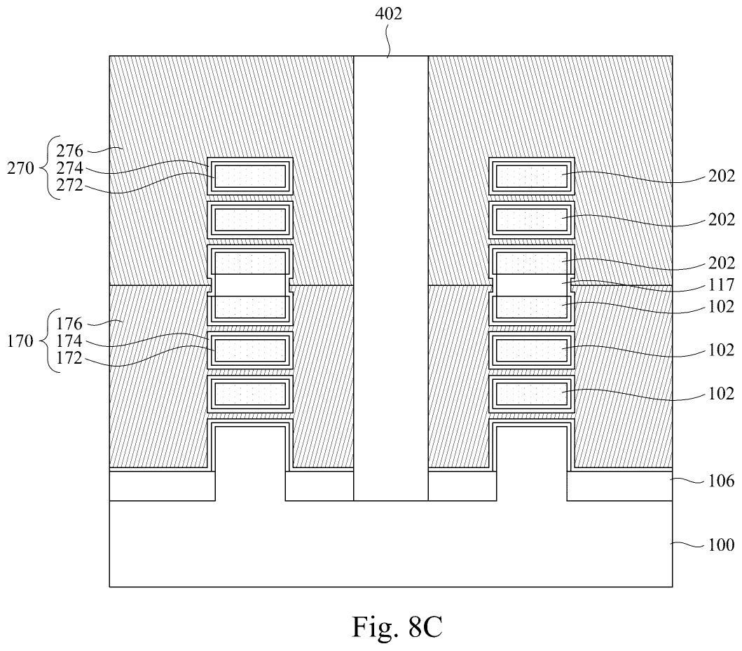

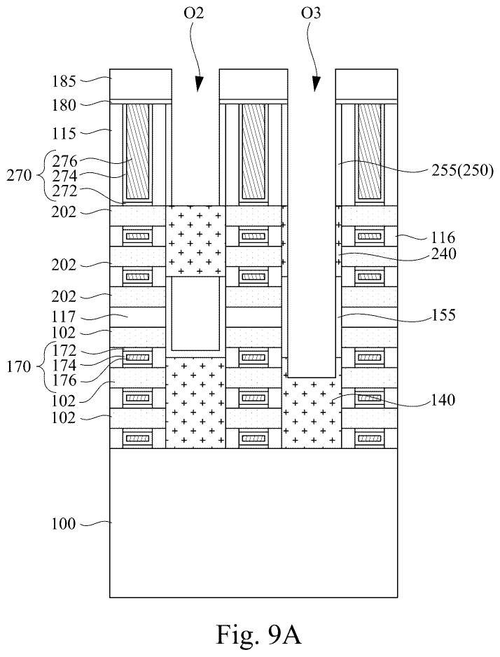

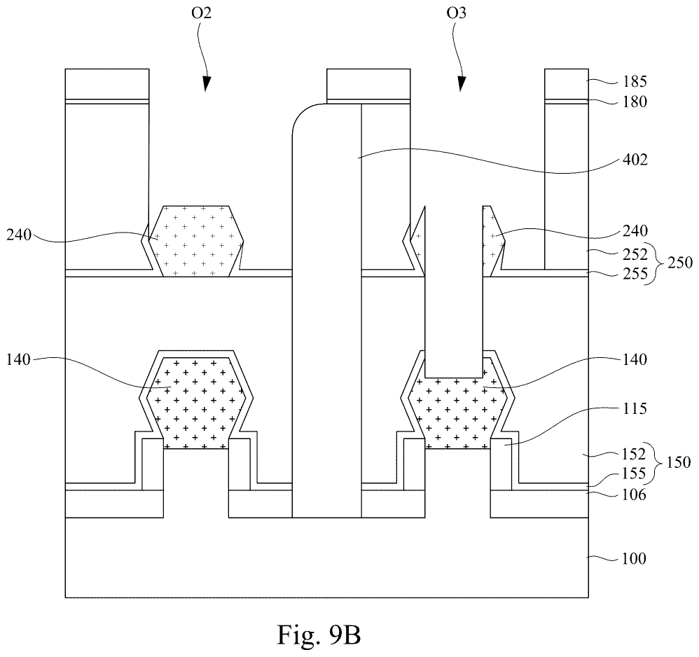

Reference is made to FIGS. 9A and 9B. An etch stop layer (ESL) 180 is formed over the isolation structures 250 and the second metal gate structures 270. Afterwards, an interlayer dielectric (ILD) layer 185 is formed over the ESL 180. The materials of the ESL 180 and the ILD layer 185 may be similar to the materials of the CESL 155 and the ILD layer 152, respectively. For example, the ESL 180 may be nitride (such as silicon nitride), and the ILD layer 185 may be oxide (such as silicon oxide). The ESL 180 and the ILD layer 185 can be formed using, for example, CVD, ALD or other suitable techniques.

An opening O2 is formed through the ILD layer 185, the ESL 180, and the isolation structure 250. On the other hand, an opening O3 is formed through the ILD layer 185, the ESL 180, the isolation structure 250, the second source/drain epitaxy structure 240, and the isolation structure 150.

With respect to the opening O2, the opening O2 may be formed by performing an etching process, in which the etching process may stops until the top surface of the corresponding second source/drain epitaxy structure 240 is exposed. In the cross-sectional view of FIG. 9A, the ILD layer 252 (see FIG. 8A) is removed during the etching process, such that the CESL 255 is exposed through the opening O2. In the cross-sectional view of FIG. 9B, the opening O2 may expose the dielectric structure 402.

With respect to the opening O3, the opening O3 may be formed by performing an etching process, in which the etching process may stops until the top surface of the corresponding first source/drain epitaxy structure 140 is exposed. In the cross-sectional view of FIG. 9A, the opening O3 may penetrate through the corresponding second source/drain epitaxy structure 240 and expose the top surface of the corresponding first source/drain epitaxy structure 140. In some embodiments, the etching process may also slightly etch the corresponding first source/drain epitaxy structure 140, such that the bottom end of the opening O3 may extend into the corresponding first source/drain epitaxy structure 140.

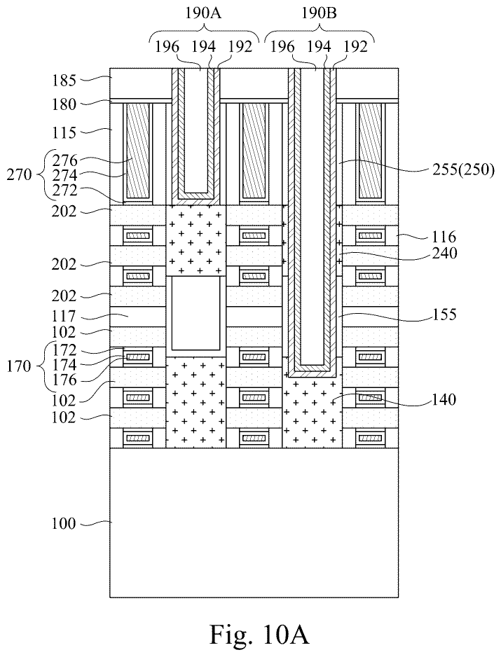

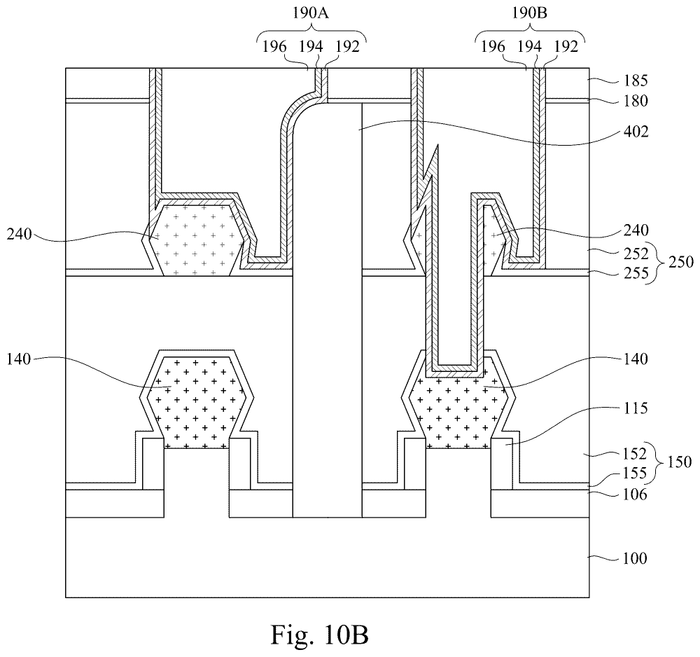

Reference is made to FIGS. 10A and 10B. A dipole layer 192 is deposited in the openings O2 and O3, a metal oxide layer 194 is then deposited over the dipole layer 192, and a metal layer 196 is then deposited over the metal oxide layer 194. Afterwards, a planarization process, such as a CMP process, is performed to remove excess materials of the dipole layer 192, the metal oxide layer 194, and the metal layer 196 until the ILD layer 185 is exposed. Accordingly, source/drain contacts 190A and 190B are formed. In greater detail, each of the source/drain contacts 190A and 190B may include a dipole layer 192, a metal oxide layer 194 over the dipole layer 192, and a metal layer 196 over the metal oxide layer 194. In some embodiments, the dipole layer 192, the metal oxide layer 194, and the metal layer 196 can be deposited using a conformal deposition process, such as CVD or ALD.

In some embodiments, the dipole layer 192 may be a metal layer, which includes Sc, Y, Ti, Zr, Hf, Al, V, Nb, Ta, Cr, Mo, Ga, In, Zn, Tl, La, Er, Yb, Dy, Gd, Ni, W, Sb, Te, Ge, or the like. In some embodiments, the metal oxide layer 194 may include TiO₂, ZnO, IGZO, In₂O₃, Ga₂O₃, NiO, Y₂O₃, La₂O₃, LaAlO₃, Ta₂O₃, or the like. The metal oxide layer 194 can also be referred to as a dielectric layer. In some embodiments, the metal layer 196 may include Ni, Mo, W, Ru, Ti, Nb, Pt, Al, Co, Pd, Ir, Re, Rh, or the like. In some embodiments, the metal element of the dipole layer 192 may be different from the metal element of the metal oxide layer 194. In some embodiments, the metal element of the dipole layer 192 may be the same as the metal element of the metal layer 196, or may be different from the metal element of the metal layer 196. In some embodiments, the metal elements of the dipole layer 192, the metal oxide layer 194, and the metal layer 196 are all different. In some embodiments, the electrical conductivities of the dipole layer 192, the metal oxide layer 194, and the metal layer 196 of the source/drain contacts 190A and 190B may be greater than an electrical conductivity of the source/drain epitaxy structures 140 and 240.

In some embodiments, titanium (Ti) silicide is commonly used for source/drain contacts. However, the contact resistance between the Ti silicide and the source/drain epitaxy structures may be limited to 2E-9 ohm-cm². This is because, like most of the metal-semiconductor contacts, Ti silicide as contact may suffer from the issue of fermi level pinning to the mid-gap of Si, resulting in a larger Schottky barrier height (SBH) and preventing further reduction of contact resistance. To further improve the contact resistance in a CFET structure, embodiments of the present disclosure provide a new contact scheme to address the above issue.

For example, as shown in FIGS. 10A and 10B, embodiments of the present disclosure provide a Metal-Metal Oxide-Dipole-Semiconductor (MODS) structure to replace the conventional Ti silicide on CFET to reduce Schottky barrier height and contact resistance. Accordingly, there are no silicide layers between the source/drain epitaxy structures 140 and 240 and the source/drain contacts 190A and 190B. As a result, the metal oxide layer (e.g., the metal oxide layer 194.) is configured to reduce the Schottky barrier height and the contact resistance, and the dipole layer 192 is configured to neutralize unfavorable dipole and to further reduce the SBH due to the band shift by the dipole, which will be discussed in more detail later.

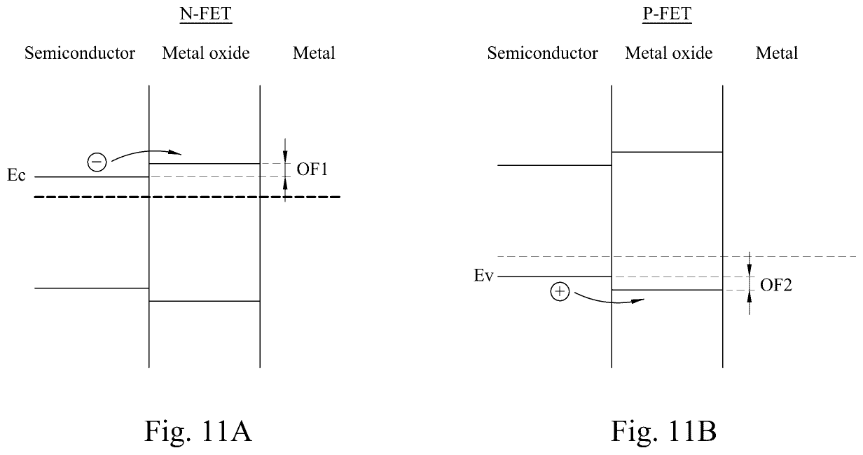

FIGS. 11A and 11B are schematic views of band structures of semiconductor devices in accordance with some embodiments of the present disclosure. FIGS. 11A and 11B illustrate band structures of an N-FET device and a P-FET device, respectively, in which each of the N-FET device and the P-FET device includes a semiconductor layer (e.g., the source/drain epitaxy structures 140 or 240), a metal oxide layer (e.g., the metal oxide layer 194), and a metal layer (e.g., metal layer 196). It is noted that, to explain how the metal oxide layer works, the dipole layer (e.g., the dipole layer 192) is not illustrated in the band structures of FIGS. 11A and 11B.

In some embodiments, the material of the metal oxide layer (e.g., the metal oxide layer 194) can be selected such that the conduction band energy (Ec) of the metal oxide layer may match the conduction band energy (Ec) of the semiconductor layer of the N-type device (e.g., the second source/drain epitaxy structure 240), and the valance band energy (Ev) of the metal oxide layer may match the valance band energy (Ev) of the semiconductor layer of the P-type device (e.g., the first source/drain epitaxy structure 140). Specifically, the material of the metal oxide layer can be selected such that the band offset OF1 (e.g., the conduction band energy difference) between the conduction band energy (Ec) of the metal oxide layer and the conduction band energy (Ec) of the semiconductor layer of the N-type device (e.g., Si) is lower than 3.0 eV, and the material of the metal oxide layer can be selected such that the band offset OF2 (e.g., the valance band energy difference) between the valance band energy (Ev) of the metal oxide layer and the valance band energy (Ev) of the semiconductor layer of the P-type device (e.g., SiGe) is lower than 3.0 eV. Accordingly, electrons and holes can pass from the semiconductor layer to the metal oxide layer by crossing a reduced energy barrier, resulting in a reduced contact resistance. However, if a Ti silicide layer is used for the source/drain contact, metal wavefunction may penetrate into the semiconductor layer and causes Fermi level pinning and an increase in Schottky barrier height (SBH), the metal oxide layer can prevent this from happening because the metal oxide layer is able to block the metal wavefunction from entering the semiconductor layer. In some embodiments, the material of the semiconductor layer of the P-type device (e.g., the first source/drain epitaxy structure 140) may be silicon germanium (SiGe), and the material of the semiconductor layer of the N-type device (e.g., the second source/drain epitaxy structure 240) may be silicon (Si).

On the other hand, referring back to FIGS. 10A and 10B, with respect to the dipole layer 192. The dipole layer 192 is strategically interposed between a semiconductor layer (e.g., the source/drain epitaxy structure 140 or 240) and a metal oxide layer (e.g., the metal oxide layer 194), and may serve a critical role in charge neutralization by facilitating the alignment and stabilization of charges at the interface. The formation of the dipole layer 192 can begin with choosing materials that naturally exhibit a dipole moment. These materials are characterized by a strong charge separation within the molecule, resulting in one end being positively charged and the other negatively charged. When applied to the interface between a semiconductor layer and a metal oxide layer, the dipoles orient themselves due to surface energy effects or molecular interactions. Their alignment is such that they oppose the intrinsic electric field generated by charge accumulation at the interface. For instance, if the metal oxide layer is formed in contact with the semiconductor layer, charge traps in the oxide can lead to undesirable shifts in threshold voltage and leakage currents. A well-aligned dipole layer can counteract these traps by creating an opposing electric field that neutralizes the trapped charges. Accordingly, the dipole layer 192 not only neutralizes charges but can also enhance the band alignment between the semiconductor layer and metal oxide layer, reducing band bending and enhancing carrier mobility. This results in reduced power consumption and improved performance for semiconductor devices.

Based on the above discussion, the material of the dipole layer 192 and the material of the metal oxide layer 194 may be selected to obtain an improved performance for semiconductor devices. In some embodiments, when a source/drain contact (e.g., the source/drain contact 190A) is in contact with only an N-type epitaxy structure (e.g., the source/drain epitaxy structure 240, such as Si), possible candidates of metal oxide layer 194 may include TiO₂, ZnO, IGZO, In₂O₃, NiO, Y₂O₃, La₂O₃, LaAlO₃, Ta₂O₃, or Ga₂O₃, and possible candidates of dipole layer 192 may include Sc, Y, Ti, Zr, Hf, Al, V, Nb, Ta, Cr, Mo, Ga, In, Zn, Tl, La, Er, Yb, Dy, Gd, Ni, W, Sb, Te, or Ge. In other embodiments, when a source/drain contact (not shown) is in contact with only a P-type epitaxy structure (e.g., the source/drain epitaxy structure 140, such as SiGe), possible candidates of metal oxide layer 194 may include TiO₂, ZnO, IGZO, In₂O₃, NiO, Y₂O₃, La₂O₃, LaAlO₃, or Ta₂O₃, and possible candidates of dipole layer 192 may include Sc, Y, Ti, Zr, Hf, Al, V, Nb, Ta, Cr, Mo, Ga, In, Zn, Tl, La, Er, Yb, Dy, Gd, Ni, W, Sb, Te, or Ge. In other embodiments, when a source/drain contact (e.g., source/drain contact 190B) is in contact with both a P-type epitaxy structure (e.g., the source/drain epitaxy structure 140, such as SiGe) and an N-type epitaxy structure (e.g., the source/drain epitaxy structure 240, such as Si), possible candidates of metal oxide layer 194 may include TiO₂, ZnO, IGZO, In₂O₃, NiO, Y₂O₃, La₂O₃, LaAlO₃, or Ta₂O₃, and possible candidates of dipole layer 192 may include Sc, Y, Ti, Zr, Hf, Al, V, Nb, Ta, Cr, Mo, Ga, In, Zn, Tl, La, Er, Yb, Dy, Gd, Ni, W, Sb, Te, or Ge. In some embodiments, the combination of the metal oxide layer 194 the dipole layer 192 may be, for example, TiO₂/Sc; TiO₂/Zr; TiO₂/Y; TiO₂/In; TiO₂/Ga, TiO₂/Zn; ZnO/Sc; ZnO/Ga; ZnO/Al; IGZO/Ni; IGZO/Ta; In₂O₃/Ni; In₂O₃/Zr; NiO/In; NiO/Zr; NiO/Zn; Ga₂O₃/In; Ta₂O₃/Nb.

The dipole layer 192 may include a thickness T1, and the metal oxide layer 194 may include a thickness T2. In some embodiments, the thickness T1 is in a range from about 0.5 nm to about 2.0 nm, and the thickness T2 is in a range from about 1.0 nm to about 3.0 nm. If the metal oxide layer 194 is too thick (e.g., much greater than 3.0 nm), because the metal oxide layer 194 is a dielectric material, the resistance of the metal oxide layer may be too high. If the metal oxide layer 194 is too thin (e.g., much lower than 1.0 nm), the metal oxide layer 194 may not be able to achieve the above discussed purpose. In some embodiments, the dipole layer 192 may be thinner than the metal oxide layer 194 (e.g., thickness T1<thickness T2). In some embodiments, the sum of the thickness T1 and the thickness T2 is less than about 3.0 nm.

Accordingly, with such configuration, the dipole layer 192 of the source/drain contacts 190A and 190B may be formed in physical contact with the first source/drain epitaxy structure 140 and/or the second source/drain epitaxy structure 240, without a metal silicide layer interposed therebetween. In FIG. 10B, the dipole layer 192 of the source/drain contact 190A may be in contact with the second source/drain epitaxy structure 240, the CESL 255, the ILD layer 252, the dielectric structure 402, the ESL 180, and the ILD layer 185. On the other hand, the dipole layer 192 of the source/drain contact 190B may be in contact with the first source/drain epitaxy structure 140, the CESL 155, the ILD layer 152, the second source/drain epitaxy structure 240, the CESL 255, the ILD layer 252, the ESL 180, and the ILD layer 185. In some embodiments, the metal oxide layer 194 may be spaced apart from the first source/drain epitaxy structure 140, the CESL 155, the ILD layer 152, the second source/drain epitaxy structure 240, the CESL 255, the ILD layer 252, the ESL 180, and the ILD layer 185 through the dipole layer 192. In some embodiments, top end of the dipole layer 192, top end of the metal oxide layer 194, and top surface of the metal layer 196 may be substantially level with each other. In some embodiments, the top end of the dipole layer 192, top end of the metal oxide layer 194, and top surface of the metal layer 196 may be substantially level with top surface of the ILD layer 195.

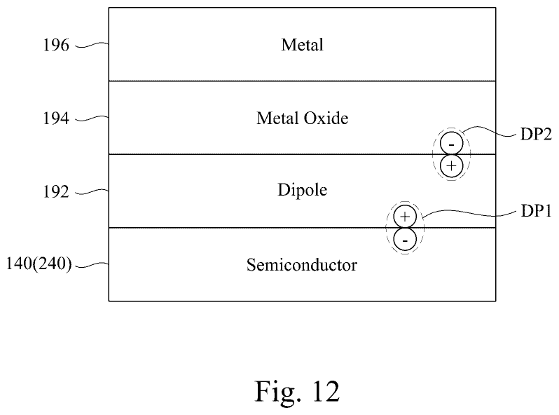

FIG. 12 is a schematic view of a semiconductor device in accordance with some embodiments of the present disclosure. In greater detail, FIG. 12 shows a Metal-Metal Oxide-Dipole-Semiconductor (MODS) structure. Here, the metal can be the metal layer 196 as discussed above, the metal oxide can be the metal oxide layer 194 as discussed above, the dipole layer can be the dipole layer 192 as discussed above, and the semiconductor layer can be the source/drain epitaxy structure 140 or 240 as discussed above.

As shown in FIG. 12, the dipole layer (e.g., dipole layer 192) is inserted between metal oxide layer (e.g., the metal oxide layer 194) and the semiconductor layer (e.g., the source/drain epitaxy structure 140 or 240). The material of the dipole layer is selected to create a first dipole DP1 at the interface between the semiconductor layer and the dipole layer, and a second dipole DP2 at the interface between the metal oxide layer and the dipole layer, in which first dipole DP1 and the second dipole DP2 include opposite directions. For example, if the direction of the first dipole DP1 is defined as from the semiconductor layer toward the dipole layer, the direction of the second dipole DP2 is then defined as from the metal oxide layer toward the dipole layer.

The opposite dipole directions of the first dipole DP1 and the second dipole DP2 may be beneficial to improve device performance. For example, in some embodiments, the first dipole DP1 may increase the Schottky barrier height (SBH) at the interface between the semiconductor layer and the dipole layer, while the second dipole DP2 may decrease the Schottky barrier height (SBH) at the interface between the metal oxide layer and the dipole layer. However, the first dipole DP1, which adversely affect the Schottky barrier height (SBH) at the interface between the semiconductor layer and the dipole layer, can be balanced out by the second dipole DP2 having an opposite direction.

On the other hand, if the dipole layer is absent, the metal oxide layer will be in contact with the semiconductor layer. A dipole having a same direction as the first dipole DP1 will be created at the interface between the metal oxide layer and the semiconductor layer, and such dipole will increase the Schottky barrier height (SBH) at the interface between the semiconductor layer and the dipole layer. Accordingly, even if the metal oxide layer can reduce Schottky barrier height (SBH) as discussed in FIGS. 11A and 11B, the dipole created between the interface between the metal oxide layer and the semiconductor layer will balance out the benefit of metal oxide layer. In contrast, by inserting a dipole layer between the metal oxide layer and the semiconductor layer, the dipole layer can neutralize unfavorable dipole (e.g., the first dipole DP1), and the present of the metal oxide layer may also be beneficial to reduce Schottky barrier height from the semiconductor layer to the metal oxide layer.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET device, which includes a bottom transistor and a top transistor. Source/drain contacts are formed electrically connected with the source/drain structures of the bottom transistor and the top transistor, respectively. The source/drain contacts each includes a dipole layer, a metal oxide layer, and a metal layer. The metal oxide layer is configured to block the wave function from the overlaying metal layer, and may be configured to reduce Schottky barrier height and contact resistance. The dipole layer is configured to neutralize unfavorable dipole and to further reduce the Schottky barrier height due to the band shift by the dipole. With such configuration, the device performance can be improved.

In some embodiments of the present disclosure, a semiconductor device includes a first device, comprising a first semiconductor channel layer, a first source/drain structure electrically connected to the first semiconductor channel layer, and a first gate structure over the first semiconductor channel layer. A contact etch stop layer (CESL) is over the first source/drain structure. An interlayer dielectric (ILD) layer is over the CESL, wherein a dielectric constant of the CESL is greater than a dielectric constant of the ILD layer. A source/drain contact extends through the ILD layer to electrically couple to the first source/drain structure, wherein an electrical conductivity of the source/drain contact is greater than an electrical conductivity of the first source/drain structure, and wherein the source/drain contact comprises a dipole layer, a metal oxide layer over the dipole layer, and a metal layer over the metal oxide layer.

In some embodiments, the dipole layer is a metal layer.

In some embodiments, a metal element of the dipole layer is different from a metal element of the metal oxide layer.

In some embodiments, the dipole layer of the source/drain contact is in physical contact with the first source/drain structure of the first device.

In some embodiments, the dipole layer is thinner than the metal oxide layer.

In some embodiments, the first device is an N-type device, and a band offset between a conduction band energy of a material of the dipole layer and a conduction band energy of a material of the first source/drain structure is less than 3.0 eV.

In some embodiments, the first device is a P-type device, and a band offset between a valance band energy of a material of the dipole layer and a valance band energy of a material of the first source/drain structure is less than 3.0 eV.

In some embodiments of the present disclosure, a semiconductor device includes a first device, comprising a first channel layer, a first source/drain structure connected to the first channel layer, and a first gate structure disposed over the first channel layer. A second device is above the first device, wherein the first device and the second device have opposite conductivity types, wherein the second device comprises a second channel layer, a second source/drain structure connected to the second channel layer, and a second gate structure disposed over the second channel layer. A gate spacer is along a sidewall of the second gate structure. A contact etch stop layer (CESL) is over the second source/drain structure, wherein a portion of the CESL extends along a sidewall of the gate spacer, such that the gate spacer is between the second gate structure and the CESL. An interlayer dielectric (ILD) layer is over the CESL. A source/drain contact extends through the ILD layer and the CESL to electrically connect the first source/drain structure of the first device and the second source/drain structure of the second device, wherein the source/drain contact is spaced apart from the second gate structure by the CESL and the gate spacer, and wherein the source/drain contact comprises a first metal layer, a dielectric layer over the first metal layer, and a second metal layer over the dielectric layer.

In some embodiments, the dielectric layer is a metal oxide layer.

In some embodiments, the first metal layer is in physical contact with the first source/drain structure of the first device and the second source/drain structure of the second device.

In some embodiments, a top end of the first metal layer, a top end of the dielectric layer, and a top surface of the second metal layer are substantially level with each other.

In some embodiments, the first device is a P-type device, and the second device is an N-type device, and wherein a band offset between a valance band energy of a material of the first metal layer and a valance band energy of a material of the first source/drain structure is less than 3.0 eV, and a band offset between a conduction band energy of the material of the first metal layer and a conduction band energy of a material of the second source/drain structure is less than 3.0 eV.

In some embodiments, a combination of the dielectric layer and the first metal layer comprises TiO₂/Sc; TiO₂/Zr; TiO₂/Y; TiO₂/In; TiO₂/Ga, TiO₂/Zn; ZnO/Sc; ZnO/Ga; ZnO/Al; IGZO/Ni; IGZO/Ta; In₂O₃/Ni; In₂O₃/Zr; NiO/In; NiO/Zr; NiO/Zn; Ga₂O₃/In; or Ta₂O₃/Nb.

In some embodiments, a thickness of the first metal layer is in a range from about 0.5 nm to about 2.0 nm, and a thickness of the dielectric layer is in a range from about 1.0 nm to about 3.0 nm.

In some embodiments of the present disclosure, a method includes forming a semiconductor device over a substrate and comprising a first transistor comprising a first channel layer, a first source/drain structure, and a first gate structure, wherein the first source/drain structure of the first transistor is covered by a first isolation structure; and a second transistor above the first transistor and comprising a second channel layer, a second source/drain structure, and a second gate structure, wherein a gate spacer has a first sidewall interfacing with a gate dielectric layer of the second gate structure and a second sidewall facing away from the second gate structure, wherein the second source/drain structure of the second transistor is covered by a second isolation structure, the second isolation structure comprises a contact stop layer (CESL) extending along and interfacing the second sidewall of the gate spacer, wherein a dielectric constant of the gate dielectric layer of the second gate structure is greater than a dielectric constant of the gate spacer or the CESL; and etching the second isolation structure, the second source/drain structure of the second transistor, and the first isolation structure to form an opening that exposes the second source/drain structure of the second transistor and the first source/drain structure of the first transistor; depositing a dipole layer in the opening; depositing a metal oxide layer over the dipole layer; and depositing a metal layer over the metal oxide layer, wherein a conductivity of the metal layer is greater than a conductivity of the second source/drain structure.

In some embodiments, the dipole layer is in physical contact with the second source/drain structure of the second transistor and the first source/drain structure of the first transistor.

In some embodiments, the dipole layer is formed lining the first source/drain structure of the first transistor, the second source/drain structure of the second transistor, the first isolation structure, and the second isolation structure.

In some embodiments, the method further includes performing a planarization to the dipole layer, the metal oxide layer, and the metal layer.

In some embodiments, the dipole layer is a metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first device, comprising:
a first semiconductor channel layer;
a first source/drain structure electrically connected to the first semiconductor channel layer; and
a first gate structure over the first semiconductor channel layer;
a contact etch stop layer (CESL) over the first source/drain structure;
an interlayer dielectric (ILD) layer over the CESL, wherein a dielectric constant of the CESL is greater than a dielectric constant of the ILD layer; and
a source/drain contact extending through the ILD layer to electrically couple to the first source/drain structure, wherein an electrical conductivity of the source/drain contact is greater than an electrical conductivity of the first source/drain structure, and wherein the source/drain contact comprises:
a dipole layer;
a metal oxide layer over the dipole layer; and
a metal layer over the metal oxide layer.

2. The semiconductor device of claim 1, wherein the dipole layer is a metal layer.

3. The semiconductor device of claim 2, wherein a metal element of the dipole layer is different from a metal element of the metal oxide layer.

4. The semiconductor device of claim 1, wherein the dipole layer of the source/drain contact is in physical contact with the first source/drain structure of the first device.

5. The semiconductor device of claim 1, wherein the dipole layer is thinner than the metal oxide layer.

6. The semiconductor device of claim 1, wherein the first device is an N-type device, and a band offset between a conduction band energy of a material of the dipole layer and a conduction band energy of a material of the first source/drain structure is less than 3.0 eV.

7. The semiconductor device of claim 1, wherein the first device is a P-type device, and a band offset between a valance band energy of a material of the dipole layer and a valance band energy of a material of the first source/drain structure is less than 3.0 eV.

8. A semiconductor device, comprising:
a first device, comprising:
a first channel layer;
a first source/drain structure connected to the first channel layer;
a first gate structure disposed over the first channel layer;
a second device above the first device, wherein the first device and the second device have opposite conductivity types, wherein the second device comprises:
a second channel layer;
a second source/drain structure connected to the second channel layer; and
a second gate structure disposed over the second channel layer;
a gate spacer along a sidewall of the second gate structure;
a contact etch stop layer (CESL) over the second source/drain structure, wherein a portion of the CESL extends along a sidewall of the gate spacer, such that the gate spacer is between the second gate structure and the CESL;
an interlayer dielectric (ILD) layer over the CESL; and
a source/drain contact extending through the ILD layer and the CESL to electrically connect the first source/drain structure of the first device and the second source/drain structure of the second device, wherein the source/drain contact is spaced apart from the second gate structure by the CESL and the gate spacer, and wherein the source/drain contact comprises:
a first metal layer;
a dielectric layer over the first metal layer; and
a second metal layer over the dielectric layer.

9. The semiconductor device of claim 8, wherein the dielectric layer is a metal oxide layer.

10. The semiconductor device of claim 8, wherein the first metal layer is in physical contact with the first source/drain structure of the first device and the second source/drain structure of the second device.

11. The semiconductor device of claim 8, wherein a top end of the first metal layer, a top end of the dielectric layer, and a top surface of the second metal layer are substantially level with each other.

12. The semiconductor device of claim 8, wherein the first device is a P-type device, and the second device is an N-type device, and wherein a band offset between a valance band energy of a material of the first metal layer and a valance band energy of a material of the first source/drain structure is less than 3.0 eV, and a band offset between a conduction band energy of the material of the first metal layer and a conduction band energy of a material of the second source/drain structure is less than 3.0 eV.

13. The semiconductor device of claim 8, wherein a combination of the dielectric layer and the first metal layer comprises TiO₂/Sc; TiO₂/Zr; TiO₂/Y; TiO₂/In; TiO₂/Ga, TiO₂/Zn; ZnO/Sc; ZnO/Ga; ZnO/Al; IGZO/Ni; IGZO/Ta; In₂O₃/Ni; In₂O₃/Zr; NiO/In; NiO/Zr; NiO/Zn; Ga₂O₃/In; or Ta₂O₃/Nb.

14. The semiconductor device of claim 8, wherein a thickness of the first metal layer is in a range from about 0.5 nm to about 2.0 nm, and a thickness of the dielectric layer is in a range from about 1.0 nm to about 3.0 nm.

15. The semiconductor device of claim 8, wherein a sum of a thickness of the first metal layer and a thickness of the dielectric layer is less than about 3.0 nm.

16. A method, comprising:
forming a semiconductor device over a substrate and comprising:
a first transistor comprising a first channel layer, a first source/drain structure, and a first gate structure, wherein the first source/drain structure of the first transistor is covered by a first isolation structure; and
a second transistor above the first transistor and comprising a second channel layer, a second source/drain structure, and a second gate structure, wherein a gate spacer has a first sidewall interfacing with a gate dielectric layer of the second gate structure and a second sidewall facing away from the second gate structure, wherein the second source/drain structure of the second transistor is covered by a second isolation structure, the second isolation structure comprises a contact stop layer (CESL) extending along and interfacing the second sidewall of the gate spacer, wherein a dielectric constant of the gate dielectric layer of the second gate structure is greater than a dielectric constant of the gate spacer or the CESL; and
etching the second isolation structure, the second source/drain structure of the second transistor, and the first isolation structure to form an opening that exposes the second source/drain structure of the second transistor and the first source/drain structure of the first transistor;
depositing a dipole layer in the opening;
depositing a metal oxide layer over the dipole layer; and
depositing a metal layer over the metal oxide layer, wherein a conductivity of the metal layer is greater than a conductivity of the second source/drain structure.

17. The method of claim 16, wherein the dipole layer is in physical contact with the second source/drain structure of the second transistor and the first source/drain structure of the first transistor.

18. The method of claim 16, wherein the dipole layer is formed lining the first source/drain structure of the first transistor, the second source/drain structure of the second transistor, the first isolation structure, and the second isolation structure.

19. The method of claim 16, further comprising performing a planarization to the dipole layer, the metal oxide layer, and the metal layer.

20. The method of claim 16, wherein the dipole layer is a metal layer.
